(19) United States
(12) Patent Application Publication
(10) Pub. No.: US 2025/0034752 A1
(43) Pub. Date: Jan. 30, 2025

(54) GALLIUM OXIDE FILM, AND MANUFACTURING DEVICE AND MANUFACTURING METHOD FOR SAME

(71) Applicants: NATIONAL UNIVERSITY CORPORATION TOKAI NATIONAL HIGHER EDUCATION AND RESEARCH SYSTEM, Nagoya-shi (JP); AGC Inc., Tokyo (JP)

(72) Inventors: Masaru HORI, Nagoya-shi (JP); Osamu Oda, Nagoya-shi (JP); Arun Kumar Dhasiyan, Nagoya-shi (JP); Atsushi Hayashi, Tokyo (JP); Nobutaka Aomine, Tokyo (JP)

(73) Assignees: NATIONAL UNIVERSITY CORPORATION TOKAI NATIONAL HIGHER EDUCATION AND RESEARCH SYSTEM, Nagoya-shi (JP); AGC Inc., Tokyo (JP)

(21) Appl. No.: 18/894,708

(22) Filed: Sep. 24, 2024

Related U.S. Application Data
(63) Continuation of application No. PCT/JP2023/011019, filed on Mar. 20, 2023.

(30) Foreign Application Priority Data
Mar. 25, 2022 (JP) 2022-050538
Feb. 20, 2023 (JP) 2023-024459

(51) Int. Cl. C30B 25/08; C30B 25/10; C30B 25/20; C30B 29/16

(52) U.S. Cl. CPC C30B 25/08; C30B 25/105; C30B 25/20; C30B 29/16

(57) ABSTRACT

A gallium oxide film production apparatus includes: a reaction chamber; a substrate disposition portion located in the reaction chamber and configured to dispose a substrate for growing a gallium oxide; a gallium element supply device configured to supply a gallium element to the substrate disposition portion; an oxygen element supply device configured to supply oxygen constituent particles to the substrate disposition portion; and a mixed gas supply device configured to supply a mixed gas containing oxygen and ozone to the oxygen element supply device. The oxygen element supply device includes a plasma generation unit configured to generate plasma from the mixed gas.

### CROSS-REFERENCE TO RELATED APPLICATIONS

This is a bypass continuation of International Patent Application No. PCT/JP2023/011019, filed on Mar. 20, 2023, which claims priority to Japanese Patent Application No. 2022-050538, filed on Mar. 25, 2022, and Japanese Patent Application No. 2023-024459, filed on Feb. 20, 2023. The contents of these applications are hereby incorporated by reference in their entireties.

### TECHNICAL FIELD

The technical field of the present invention relates to a gallium oxide film and a production apparatus and a production method for the same.

### BACKGROUND ART

Gallium oxide (Ga₂O₃) has various crystal structures, including α-type, β-type, γ-type, δ-type, and ε-type. Among these, a β-gallium oxide (β-Ga₂O₃) is a stable phase at a low temperature and a normal pressure. The β-gallium oxide has a band gap of about 4.5 eV to 4.9 eV, which is larger than band gaps of 4H-SiC (3.26 eV) and GaN (3.39 eV). Therefore, the β-gallium oxide is expected to be a semiconductor material having high breakdown strength.

For example, Patent Literature 1 discloses a technique of growing a β-gallium oxide single crystal film by supplying a gallium element from a first cell 13a in a vacuum tank 10 to a β-gallium oxide substrate 2, and supplying an oxygen gas containing ozone to the β-gallium oxide substrate 2. In addition, Non Patent Literature 1 discloses a technique of treating an oxygen gas with rf-plasma in using a molecular beam epitaxy (MBE) device in order to grow a β-gallium oxide.

### CITATION LIST

### Patent Literature

Patent Literature 1: JP2013-56802A

### Non-Patent Literature

Non Patent Literature 1: E. G. Villora, et al., β-Ga2O3 and single-crystal phosphors for high-brightness white LEDs&LDs, and β-Ga2O3 potential for next generation of power devices, Proc. of SPIE Vol. 8987 89871U-1 to U-12 (2014)
Non Patent Literature 2: Development of an ultra-short gap ozone generator—High concentration ozone generation for pulp bleaching—(Masaki Kuzumoto, Yoichiro Tabata, Satoru Shiono, JAPAN TAPPI JOURNAL, Vol. 51, No. 2, pp. 111-116 (1997) (JAPAN TAPPI))

### SUMMARY OF INVENTION

### Technical Problem

In a gallium oxide produced by a production apparatus in Patent Literature 1, crystallinity of the gallium oxide is poor, and flatness of the gallium oxide is poor. In addition, a growth temperature is as high as 700° C. or higher, and a growth rate is as slow as about 0.1 μm/h.

A problem that the technique of the present invention aims to solve is to provide a gallium oxide film having excellent crystallinity and excellent flatness obtained by epitaxially growing a gallium oxide, and a production apparatus and a production method for the same.

### Solution to Problem

A gallium oxide film production apparatus according to the present embodiment includes: a reaction chamber; a substrate disposition portion located in the reaction chamber and configured to dispose a substrate for growing a gallium oxide; a gallium element supply device configured to supply a gallium element to the substrate disposition portion; an oxygen element supply device configured to supply oxygen constituent particles to the substrate disposition portion; and a mixed gas supply device configured to supply a mixed gas containing oxygen and ozone to the oxygen element supply device.

The gallium oxide film production apparatus is an apparatus for growing a gallium oxide on a substrate in the substrate disposition portion. The oxygen element supply device includes a plasma generation unit configured to generate plasma from the mixed gas.

The gallium oxide film production apparatus can supply, to the substrate, oxygen constituent particles that react easily with the gallium element. Therefore, with the production apparatus, in an epitaxially grown gallium oxide film, the crystallinity of the gallium oxide film is good, and the flatness of the gallium oxide film is good. In addition, the growth rate is fast, and the growth temperature is low. In the present description, the term “epitaxial” refers to that a peak of a single orientation is observed when a gallium oxide film is subjected to θ-2θ measurement using an X-ray diffraction device.

A gallium oxide film production method according to the present embodiment includes: generating plasma from a mixed gas containing oxygen and ozone to dissociate the ozone into oxygen constituent particles, and supplying the oxygen constituent particles to a reaction chamber under a reduced pressure; supplying a gallium element to the reaction chamber; and epitaxially growing a β-gallium oxide on a β-gallium oxide substrate in the reaction chamber.

A gallium oxide film according to the present embodiment has a thickness of 0.5 μm or more and a breakdown voltage of 80 V/μm or more.

### Advantageous Effects of Invention

According to the present invention, it is possible to provide a gallium oxide film having excellent crystallinity and excellent flatness obtained by epitaxially growing a gallium oxide, and a production apparatus and a production method for the same.

### BRIEF DESCRIPTION OF DRAWINGS

FIG. 1 is a schematic configuration diagram showing a structure of a gallium oxide body 100 according to a first embodiment.

FIG. 2 is a schematic configuration diagram showing a production apparatus 1000 for the gallium oxide body 100 according to the first embodiment.

FIG. 3 is a schematic configuration diagram showing an internal structure of an ozonizer 1700 of the production apparatus 1000 according to the first embodiment.

FIG. 4 is a schematic configuration diagram showing a structure of an oxygen element supply device 1400 of the production apparatus 1000 according to the first embodiment.

FIG. 5 is a conceptual diagram illustrating a 2p orbital of a singlet oxygen atom O (¹D).

FIG. 6 is a conceptual diagram illustrating a 2p orbital of a triplet oxygen atom O (³P).

FIG. 7 is a conceptual diagram showing a state where a gallium atom (Ga) and an oxygen atom (O) react with each other on a surface of a substrate or the like to form Ga₂O.

FIG. 8 is a conceptual diagram showing a state where Ga₂O and an oxygen atom (O) react with each other on a surface of a substrate or the like to form Ga₂O₃.

FIG. 9 is a conceptual diagram showing a state where Ga₂O adsorbed on the surface of the substrate is desorbed as a gas from the surface of the substrate.

FIG. 10 is a table showing experiment conditions.

FIG. 11 is a scanning electron microscope photograph showing a surface of a deposit on a substrate in the case where a mixed gas containing oxygen, ozone, and an Ar gas is not irradiated with second plasma.

FIG. 12 is a scanning electron microscope photograph showing a cross section of the deposit on the substrate in the case where the mixed gas containing oxygen, ozone, and an Ar gas is not irradiated with the second plasma.

FIG. 13 is a scanning electron microscope photograph showing a surface of a deposit on the substrate in the case where a mixed gas containing oxygen and an Ar gas is irradiated with the second plasma.

FIG. 14 is a scanning electron microscope photograph showing a cross section of the deposit on the substrate in the case where the mixed gas containing oxygen and an Ar gas is irradiated with the second plasma.

FIG. 15 is a scanning electron microscope photograph showing a surface of a deposit on the substrate in the case where the mixed gas containing oxygen, ozone, and an Ar gas is irradiated with the second plasma.

FIG. 16 is a scanning electron microscope photograph showing a cross section of the deposit on the substrate in the case where the mixed gas containing oxygen, ozone, and an Ar gas is irradiated with the second plasma.

FIG. 17 is a scanning electron microscope photograph showing a surface of a deposit on the substrate in the case where a mixed gas containing oxygen and ozone is irradiated with the second plasma.

FIG. 18 is a scanning electron microscope photograph showing a cross section of the deposit on the substrate in the case where the mixed gas containing oxygen and ozone is irradiated with the second plasma.

FIG. 19 is a pattern showing an X-ray diffraction result of a β-gallium oxide substrate.

FIG. 20 is a pattern showing an X-ray diffraction result of a β-gallium oxide film formed on the substrate under a condition 4.

FIG. 21 is a graph showing a density of the triplet oxygen atom O (³P).

FIG. 22 is a graph showing a breakdown voltage (V/μm) of a β-gallium oxide film.

FIG. 23 is a graph showing current-voltage properties of a β-gallium oxide film.

FIG. 24 is a graph showing a relationship between a growth temperature and a growth rate of a β-gallium oxide film.

FIG. 25 is a pattern showing an X-ray diffraction result of a β-gallium oxide film formed on the substrate under a condition 5.

FIG. 26 is a pattern showing an X-ray diffraction result of a β-gallium oxide film formed on the substrate under a condition 6.

### DESCRIPTION OF EMBODIMENTS

Hereinafter, specific embodiments are described using a gallium oxide film production apparatus and production method as an example. However, the technique in the present description is not limited to these embodiments.

In the present description, oxygen constituent particles are particles containing oxygen atoms, including a singlet oxygen atom and a triplet oxygen atom, an oxygen molecule, ozone, or excited states thereof.

### First Embodiment

### 1. Gallium Oxide Body

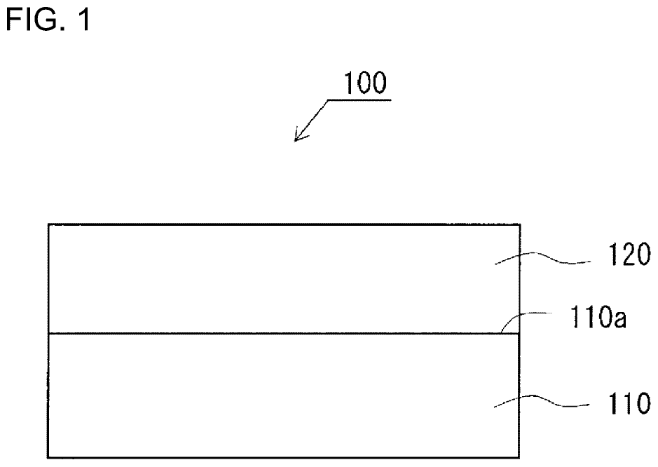

FIG. 1 is a schematic configuration diagram showing a structure of a gallium oxide body 100 according to a first embodiment. As shown in FIG. 1, the gallium oxide body 100 includes a β-gallium oxide substrate 110 and a β-gallium oxide film 120. The β-gallium oxide film 120 is formed on a first surface 110a of the β-gallium oxide substrate 110.

The β-gallium oxide substrate 110 is, for example, a bulk β-gallium oxide substrate. The β-gallium oxide substrate 110 is, for example, a substrate oriented in a (001) plane. Alternatively, the β-gallium oxide substrate 110 may be a template in which a β-gallium oxide is grown on another substrate. That is, it is sufficient that the β-gallium oxide substrate 110 is a substrate having a β-gallium oxide on a surface. The β-gallium oxide substrate is a substrate having a single crystal or a crystal close to a single crystal of a β-gallium oxide on the surface.

The β-gallium oxide film 120 is a single crystal or a crystal close to a single crystal formed by epitaxially growing a β-gallium oxide. The β-gallium oxide film 120 is, for example, a film oriented in the (001) plane. Note that, in the case where a few impurities are mixed in to grow an n-type or β-type gallium oxide semiconductor, the β-gallium oxide film 120 may contain the impurities. In addition, the β-gallium oxide film 120 may be a film oriented in a (40-1) plane or a film oriented in a (010) plane.

### 2. Production Apparatus

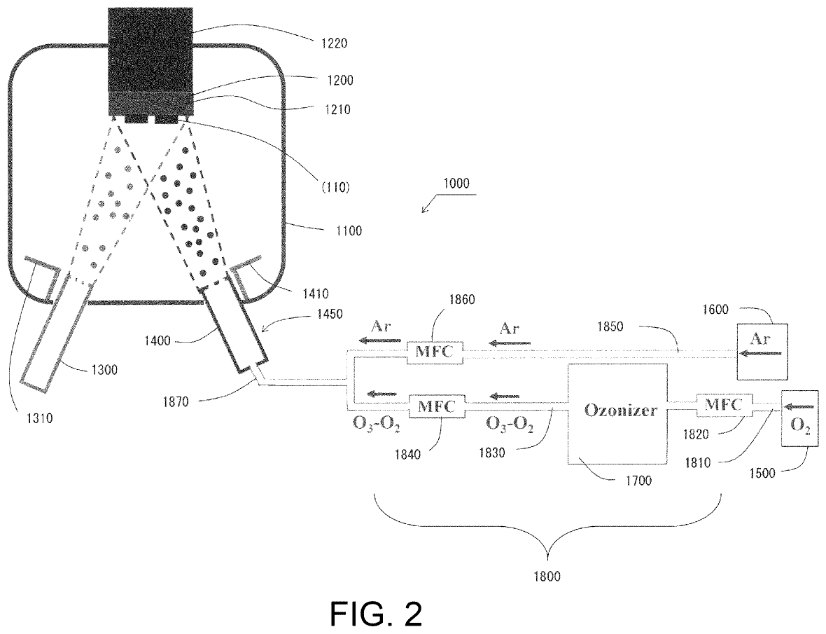

FIG. 2 is a schematic configuration diagram showing a production apparatus 1000 for the gallium oxide body 100 according to the first embodiment. The production apparatus 1000 is an apparatus for epitaxially growing the β-gallium oxide film 120 on the β-gallium oxide substrate 110.

The production apparatus 1000 includes a reaction chamber 1100, a substrate disposition portion 1200, a gallium element supply device 1300, an oxygen element supply device 1400, an oxygen gas supply unit 1500, an inert gas supply unit 1600, a mixed gas supply device 1800, and a heating device 1220. Here, the mixed gas supply device includes an ozonizer 1700, an oxygen gas supply pipe 1810, a mass flow controller 1820, an ozone-oxygen mixed gas supply pipe 1830, a mass flow controller 1840, an inert gas supply pipe 1850, a mass flow controller 1860, and a mixed gas supply pipe 1870.

The reaction chamber 1100 is a chamber for growing the β-gallium oxide film 120 on the β-gallium oxide substrate 110. The reaction chamber 1100 accommodates the substrate disposition portion 1200 therein.

The substrate disposition portion 1200 is used for disposing the β-gallium oxide substrate 110 in the reaction chamber 1100. The substrate disposition portion 1200 includes a susceptor 1210 for supporting the β-gallium oxide substrate 110. The susceptor 1210 is accommodated in the reaction chamber 1100.

The gallium element supply device 1300 is a device for supplying a gallium element (Ga) to the β-gallium oxide substrate 110 in the substrate disposition portion 1200. The gallium element supply device 1300 may be any device capable of supplying the gallium element.

The gallium element supply device 1300 may be, for example, a Knudsen cell. In the case of a Knudsen cell, the gallium element supply device 1300 includes a shutter 1310. The shutter 1310 allows or blocks communication between the gallium element supply device 1300 and the reaction chamber 1100. The gallium element supply device 1300 may include a heating device and a cooling device.

The oxygen element supply device 1400 is a device for supplying oxygen constituent particles to the β-gallium oxide substrate 110 in the substrate disposition portion 1200. The oxygen element supply device 1400 includes a shutter 1410 and a plasma generation unit 1450. The shutter 1410 allows or blocks communication between the oxygen element supply device 1400 and the reaction chamber 1100. The oxygen element supply device 1400 may include a heating device and a cooling device.

The oxygen gas supply unit 1500 is a device that supplies an oxygen gas to the oxygen element supply device 1400. The gas to be supplied to the oxygen element supply device 1400 is not actually only an oxygen gas. The oxygen gas supply pipe 1810 in the mixed gas supply device 1800 is a pipe through which the oxygen gas from the oxygen gas supply unit 1500 is supplied to the ozonizer 1700 in the mixed gas supply device 1800. In addition, in the mixed gas supply device 1800, the mass flow controller 1820 adjusts a flow rate of the oxygen gas flowing into the ozonizer 1700.

The inert gas supply unit 1600 is a device that supplies an inert gas to the oxygen element supply device 1400. The inert gas is, for example, an Ar gas. The inert gas supply pipe 1850 in the mixed gas supply device 1800 is a pipe through which the inert gas from the inert gas supply unit 1600 is supplied to the oxygen element supply device 1400. The mass flow controller 1860 constituting the mixed gas supply device 1800 adjusts a flow rate of the inert gas flowing into the oxygen element supply device 1400. Actually, the inert gas supply unit 1600 supplies the inert gas to the mixed gas supply pipe 1870.

The ozonizer 1700 constituting the mixed gas supply device 1800 supplies a mixed gas containing oxygen and ozone to the oxygen element supply device 1400. The ozonizer 1700 is, for example, a first plasma generation device that generates plasma from an oxygen gas. The ozonizer 1700 ozonizes a portion of the oxygen gas supplied from the oxygen gas supply unit 1500, generating a mixed gas containing oxygen and ozone.

The ozonizer 1700 has a capacity of setting a concentration of ozone to 5 vol % or more of a total volume of oxygen and ozone in the mixed gas containing oxygen and ozone. The concentration of ozone is preferably 10 vol % or more, more preferably 20 vol % or more, and still more preferably 25 vol % or more. Here, the total volume of oxygen and ozone does not include the volume of gases other than oxygen and ozone.

The ozone-oxygen mixed gas supply pipe 1830 in the mixed gas supply device 1800 is a pipe through which the mixed gas containing oxygen and ozone supplied from the ozonizer 1700 is supplied to the oxygen element supply device 1400. The mass flow controller 1840 in the mixed gas supply device 1800 adjusts a flow rate of the mixed gas containing oxygen and ozone flowing into the oxygen element supply device 1400. Note that, in the case where the ozonizer 1700 and the oxygen element supply device 1400 are directly connected to each other, the ozone-oxygen mixed gas supply pipe 1830 and the mass flow controller 1840 are not necessary in the mixed gas supply device 1800.

The mixed gas supply pipe 1870 in the mixed gas supply device 1800 is a pipe through which a mixed gas for generating plasma is supplied to the oxygen element supply device 1400. Here, the mixed gas for generating plasma is a mixed gas containing oxygen, ozone, and an inert gas. In the mixed gas supply pipe 1870, the inert gas and the mixed gas containing oxygen and ozone are mixed with each other. Note that, as to be described later, the mixed gas for generating plasma does not have to contain an inert gas. In this case, the inert gas supply unit 1600, the inert gas supply pipe 1850, and the mass flow controller 1860 are not necessary in the mixed gas supply device 1800.

The production apparatus 1000 includes the heating device 1220 for heating the β-gallium oxide substrate 110. The heating device 1220 has a function of setting a temperature of the substrate disposition portion 1200 to 0° C. or higher and 700° C. or lower, or to room temperature or higher and 700° C. or lower.

### 3. Plasma Generation Unit

### 3-1. First Plasma Generation Unit

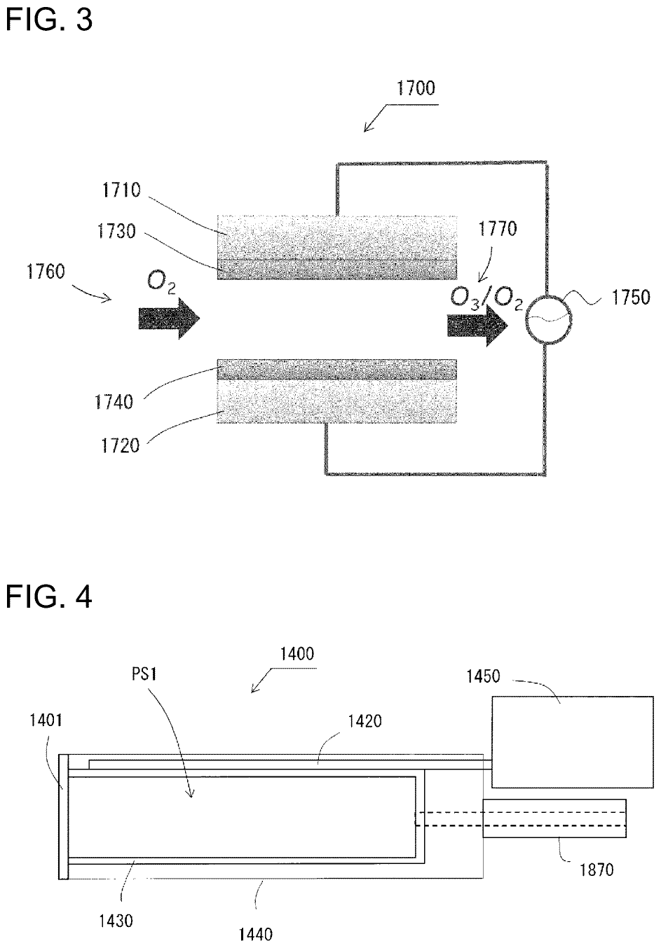

FIG. 3 is a diagram showing an internal structure of the ozonizer 1700 of the production apparatus 1000 according to the first embodiment. The ozonizer 1700 is a first plasma generation unit that generates first plasma for generating plasma from an oxygen gas. The ozonizer 1700 generates a mixed gas containing oxygen and ozone from the oxygen gas by using the first plasma. That is, the ozonizer 1700 converts a portion of the oxygen gas into ozone.

The ozonizer 1700 generates plasma between electrodes by dielectric barrier discharge. The ozonizer 1700 includes a first electrode 1710, a second electrode 1720, a first dielectric layer 1730, a second dielectric layer 1740, a voltage application unit 1750, a gas inlet 1760, and a gas outlet 1770.

The first dielectric layer 1730 is disposed on a surface of the first electrode 1710, and the second dielectric layer 1740 is disposed on a surface of the second electrode 1720. The first electrode 1710 and the second electrode 1720 face each other with the first dielectric layer 1730 and the second dielectric layer 1740 sandwiched therebetween. Plasma is generated in a space between the first dielectric layer 1730 and the second dielectric layer 1740.

The voltage application unit 1750 applies a voltage between the first electrode 1710 and the second electrode 1720. Accordingly, plasma is generated in the space between the first dielectric layer 1730 and the second dielectric layer 1740.

The gas inlet 1760 allows an oxygen gas to flow into the ozonizer 1700. The gas outlet 1770 allows a mixed gas containing oxygen and ozone to flow out of the ozonizer 1700.

The ozonizer 1700 generates a mixed gas containing oxygen and ozone. The concentration of ozone is, for example, 5 vol % or more of the total volume of oxygen and ozone in the mixed gas containing oxygen and ozone. The concentration of ozone is preferably 10 vol % or more, more preferably 20 vol % or more, and still more preferably 25 vol % or more. Note that, in the case where the concentration of ozone is less than 5 vol %, it is possible for a gallium oxide to grow, but both the growth rate and the growth temperature are very low, making it difficult to put the apparatus into industrial practical use.

Since it is desired to decompose ozone in order to grow Ga₂O₃, the concentration of ozone is preferably high. Actually, since it is difficult to convert all of oxygen into ozone, the concentration of ozone may be, for example, 50 vol % or less of the total volume of oxygen and ozone in the mixed gas containing oxygen and ozone.

The flow rate of the oxygen gas supplied to the ozonizer 1700 is, for example, 100 sccm or more and 1000 sccm or less. However, the flow rate is not limited to the above, and other flow rates may be used.

The ozonizer 1700 has a plasma power of, for example, 80 W or more and 100 W or less.

The ozonizer 1700 has an internal pressure of, for example, 0.05 MPa or more and 0.1 MPa or less.

### 3-2. Second Plasma Generation Unit

FIG. 4 is a schematic configuration diagram showing a structure of the oxygen element supply device 1400 of the production apparatus 1000 according to the first embodiment. The plasma generation unit 1450 is a second plasma generation unit that generates plasma from the mixed gas containing oxygen and ozone in the oxygen element supply device 1400. The second plasma mainly decomposes ozone and generates oxygen constituent particles.

The oxygen element supply device 1400 includes an orifice 1401, an ICP antenna 1420, an insulating pipe 1430, a shield cover 1440, the plasma generation unit 1450, and a plasma generation chamber PS1.

The orifice 1401 is a perforated plate for allowing a gas to flow out from the oxygen element supply device 1400. The ICP antenna 1420 is used for exciting plasma in the plasma generation chamber PS1. The insulating pipe 1430 is a pipe that covers a periphery of the plasma generation chamber PS1. The shield cover 1440 is a cover that further covers an outer side of the insulating pipe 1430.

The plasma generation unit 1450 is the second plasma generation unit that generates second plasma in the oxygen element supply device 1400. The plasma generation unit 1450 applies a high frequency voltage to the mixed gas containing oxygen and ozone in the oxygen element supply device 1400 to generate plasma. The plasma generation unit 1450 includes a matching box. The matching box is used for efficiently providing a high frequency power to the ICP antenna 1420. The plasma generation chamber PS1 is a space in the oxygen element supply device 1400. The mixed gas containing oxygen and ozone is supplied into the plasma generation chamber PS1 and converted into plasma.

A plasma output of the plasma generation unit 1450 is, for example, 600 W or more and 1000 W or less. As to be described later, a collision cross section of a reaction in which ozone collides with electrons to generate an oxygen molecule and a singlet oxygen atom O (¹D) has a peak where electron energy is in the vicinity of 3 eV, and is 1×10⁻¹⁷ cm² or more in a range of about 1 eV or more and 50 eV or less. Therefore, it is desirable that the electron energy generated by the plasma generation unit 1450 includes a range of about 1 eV or more and 50 eV or less.

Note that, since the ozonizer 1700 and the plasma generation unit 1450 are located at positions spatially separated from each other, the first plasma and the second plasma do not communicate with each other. However, in the case of an integrated apparatus, the first plasma and the second plasma may partially overlap each other.

### 4. Chemical Reaction and Product

### 4-1. Oxygen Atom

First, the oxygen atom thought to be involved in the reaction is described.

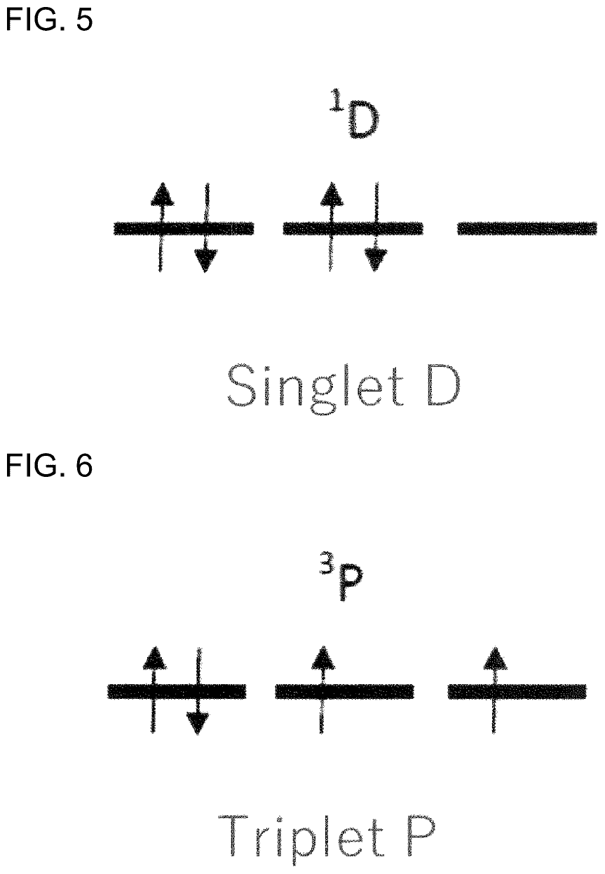

FIG. 5 is a conceptual diagram illustrating a 2p orbital of a singlet oxygen atom O (¹D). In FIG. 5, all electrons in the 2p orbital are paired.

FIG. 6 is a conceptual diagram illustrating a 2p orbital of a triplet oxygen atom O (³P). In FIG. 6, there is one pair of electrons and two unpaired electrons in the 2p orbital.

Energy of the singlet oxygen atom O (¹D) is about 1.97 eV higher than energy of the triplet oxygen atom O (³P), which is a ground state of the oxygen atom. Therefore, the singlet oxygen atom O (¹D) transitions to the triplet oxygen atom O (³P) after a certain period of time. In addition, an oxidizing power of the singlet oxygen atom O (¹D) is stronger than an oxidizing power of the triplet oxygen atom O (³P). Note that, a redox potential of the oxygen constituent particles is as follows. In this way, the oxidizing power of the triplet oxygen atom O (³P) is stronger than that of ozone, and further, the oxidizing power of the singlet oxygen atom O (¹D) is the strongest although the redox potential is unknown.
Oxygen molecule (ground state): 1.23 eV
Ozone: 2.08 eV
Triplet oxygen atom O (³P): 2.42 eV
Singlet oxygen atom O (¹D): 4.39 eV

### 4-2. Surface of Substrate

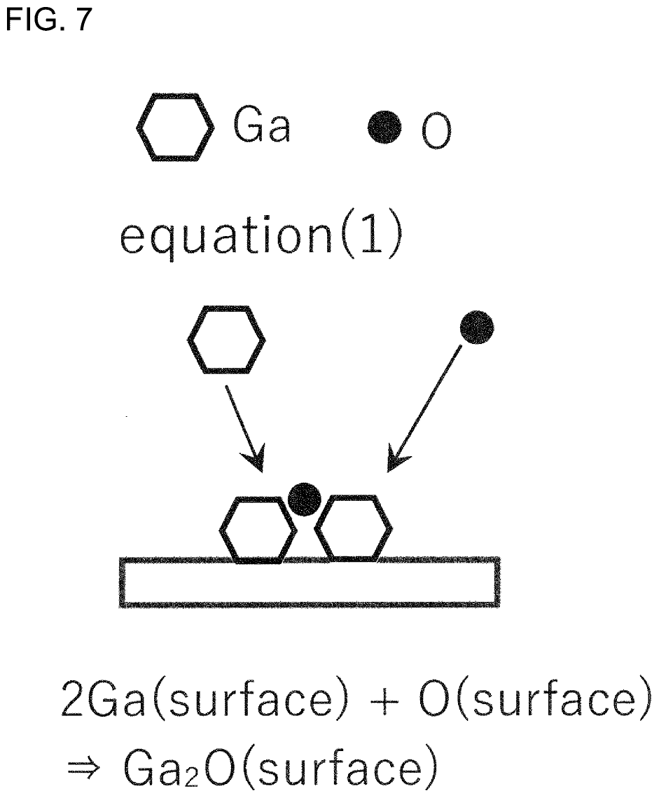

FIG. 7 is a conceptual diagram showing a state where a gallium atom (Ga) and an oxygen atom (O) react with each other on a surface of a substrate or the like to form Ga₂O. FIG. 7 shows the following reaction equation. Here, “surface” refers to a state where the element or the like is adsorbed on the surface of the substrate.

$$2 Ga ( surface ) + O ( surface ) \to {Ga}_{2} O ( surface ) \qquad ( 1 )$$

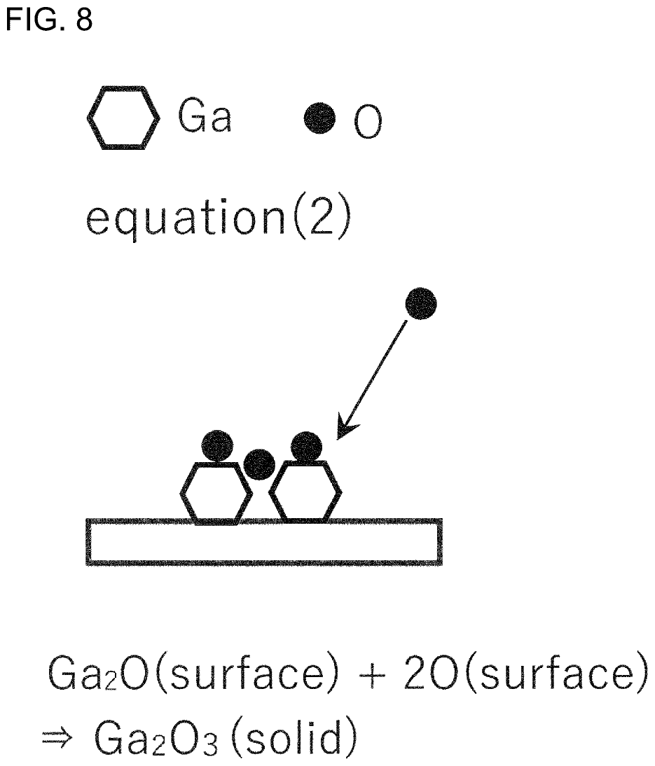

FIG. 8 is a conceptual diagram showing a state where Ga₂O and an oxygen atom (O) react with each other on a surface of a substrate or the like to form Ga₂O₃. FIG. 8 shows the following reaction equation.

$${Ga}_{2} O ( surface ) + 2 O ( surface ) \to {Ga}_{2} {O}_{3} ( solid ) \qquad ( 2 )$$

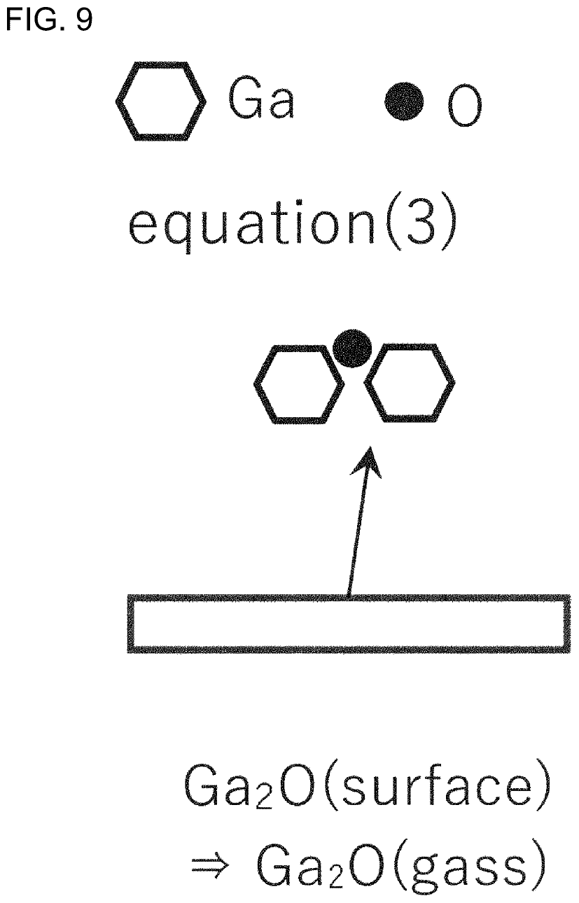

FIG. 9 is a conceptual diagram showing a state where Ga₂O adsorbed on the surface of the substrate is desorbed as a gas from the surface of the substrate. FIG. 9 shows the following reaction equation.

$${Ga}_{2} O ( surface ) \to {Ga}_{2} O ( gas ) \qquad ( 3 )$$

As described above, it is thought that Ga₂O₃ is generated through the steps of the equation (1) and the equation (2). It is thought that the stronger the oxidizing power of the oxygen atom, the faster the reaction rate in the equation (1) and the equation (2). Therefore, it is preferable to supply as many singlet oxygen atoms O (¹D) as possible.

The reaction in the equation (3) starts at about 300° C. or higher. It is also thought that the higher the substrate temperature, the faster the reaction rate. Therefore, the substrate temperature is preferably 300° C. or lower.

In the related art, it is thought that, in order to grow a gallium oxide using the triplet oxygen atom O (³P) or ozone, which has a weaker oxidizing power than the singlet oxygen atom O (¹D) (see the equation (2)), it is necessary to grow a gallium oxide at a high temperature of about 700° C. to compensate for the weak oxidizing power. On the other hand, it is presumed that the high temperature of about 700° C. accelerates the reaction in the equation (3), slowing down the growth rate of the gallium oxide.

In contrast, in the technique according to the present embodiment, since it is thought that the gallium oxide is grown using the oxygen atom, including the singlet oxygen atom O (¹D) having a stronger oxidizing power, it is thought that the gallium oxide can be grown even at a temperature of 300° C. or lower (see the equation (2)), and further, the growth rate of the gallium oxide is increased since the reaction in the equation (3) can be prevented. Alternatively, it is thought that, when a large quantity of triplet oxygen atoms O (³P) can be supplied to the surface of the substrate through transition of the singlet oxygen atom O (¹D) generated in a large quantity, the gallium oxide can be grown at a temperature of 300° C. or lower in the present technique.

### 4-3. Generation of Oxygen Atom

Non Patent Literature 2 discloses that oxygen atoms are generated by collisions between oxygen molecules and electrons in a discharge space. In Non Patent Literature 2, as the equation (1), a reaction in which an oxygen molecule collides with an electron to generate a triplet oxygen atom O (³P) and a singlet oxygen atom O (¹D) is shown (p 112 of Non Patent Literature 2).

In addition, in Non Patent Literature 2, as the equation (2), a reaction in which an oxygen molecule collides with an electron to generate two triplet oxygen atoms O (³P) is shown (p 112 of Non Patent Literature 2).

Further, in Non Patent Literature 2, as the equation (3), a reaction in which ozone collides with an electron to generate an oxygen molecule and a singlet oxygen atom O (¹D) is shown (p 112 of Non Patent Literature 2).

Further, in Non Patent Literature 2, FIG. 1 shows a graph showing a dissociation collision cross section of ozone (p 112 of Non Patent Literature 2), and it is seen that the larger the dissociation collision cross section of ozone, the more likely the reaction is to occur.

According to the FIG. 1 in Non Patent Literature 2, energy corresponding to a peak in the equation (1) in Non Patent Literature 2 is approximately 30 eV Energy corresponding to a peak in the equation (2) in Non Patent Literature 2 is approximately 10 eV Energy corresponding to a peak in the equation (3) in Non Patent Literature 2 is approximately 3 eV.

When comparing the energy corresponding to the peak in the equation (1) in Non Patent Literature 2 with the energy corresponding to the peak in the equation (3) in Non Patent Literature 2, the energy of the peak in the equation (3) in Non Patent Literature 2 is about one tenth of the energy of the peak in the equation (1) in Non Patent Literature 2. Therefore, it is thought that, as in the equation (3) in Non Patent Literature 2, when ozone is once generated and then decomposed, more singlet oxygen atoms O (¹D) can be generated.

Therefore, it is thought that, when the plasma generation unit 1450 generates plasma from the mixed gas containing oxygen and ozone, ozone is dissociated to generate more singlet oxygen atoms O (¹D). Alternatively, it is thought that, a large quantity of triplet oxygen atoms O (³P) are generated through the transition of the singlet oxygen atoms O (¹D). Note that, this prediction is based on theoretical considerations, and a density of the singlet oxygen atom O (¹D) has not yet been measured. The apparatus configuration and effects resulting therefrom in the present embodiment are not restricted by the above theoretical considerations.

### 5. Gallium Oxide Body Production Method

The β-gallium oxide substrate 110 is attached to the susceptor 1210. In addition, the β-gallium oxide substrate 110 is heated by a heater. The pressure in the reaction chamber 1100 is reduced.

An oxygen gas is supplied to the ozonizer 1700 by the oxygen gas supply unit 1500. The oxygen gas is subjected to a plasma treatment by using the first plasma generated by the ozonizer 1700. Accordingly, in the ozonizer 1700, a mixed gas containing oxygen and ozone is generated. On the other hand, an Ar gas is supplied from the inert gas supply unit 1600 to the mixed gas supply pipe 1870. The mixed gas containing oxygen and ozone and the Ar gas are mixed in the mixed gas supply pipe 1870 to be a mixed gas containing oxygen, ozone, and an Ar gas.

The plasma generation unit 1450 generates the second plasma in the oxygen element supply device 1400. A mixed gas for generating plasma is a mixed gas containing oxygen, ozone, and an Ar gas. Accordingly, it is thought that, ozone mainly decomposes, generating an oxygen molecule and an oxygen radical having a strong oxidizing power that contain a large quantity of singlet oxygen atoms O (¹D). Here, the oxygen radical contains a singlet oxygen atom O (¹D) and a triplet oxygen atom O (³P). The singlet oxygen atom O (¹D) transitions to the triplet oxygen atom O (³P) at a certain rate. These oxygen constituent particles are supplied to the β-gallium oxide substrate 110.

On the other hand, a gallium element (Ga) is supplied from the gallium element supply device 1300 to the β-gallium oxide substrate 110. Ga reacts with the oxygen radical and the like on the surface of the β-gallium oxide substrate 110, and a flat β-gallium oxide is generated on the β-gallium oxide substrate 110.

In this way, in a β-gallium oxide film production method, the mixed gas containing oxygen and ozone is generated by generating plasma from oxygen, ozone is dissociated into the oxygen molecule and the oxygen radical by generating plasma from the mixed gas, the generated gas is supplied to the reaction chamber 1100 under a reduced pressure, and the gallium element is supplied to the reaction chamber 1100. Accordingly, the β-gallium oxide film 120 is epitaxially grown on the β-gallium oxide substrate 110 in the reaction chamber 1100.

The reaction chamber 1100 has an internal pressure of, for example, 0.005 Pa or more and 0.1 Pa or less.

The temperature of the β-gallium oxide substrate 110 is, for example, 0° C. or higher and 700° C. or lower. The temperature of the β-gallium oxide substrate 110 is preferably 0° C. or higher and 500° C. or lower, more preferably 0° C. or higher and 450° C. or lower, still more preferably 0° C. or higher and 400° C. or lower, even more preferably 0° C. or higher and 350° C. or lower, even still more preferably 10° C. or higher and 350° C. or lower, particularly preferably 100° C. or higher and 350° C. or lower, and most preferably 200° C. or higher and 350° C. or lower. The temperature of the β-gallium oxide substrate 110 may be 20° C., which is about room temperature, or higher.

The concentration of ozone to be supplied to the oxygen element supply device 1400 is, for example, preferably 5 vol % or more, more preferably 10 vol % or more, still more preferably 20 vol % or more, and even more preferably 25 vol % or more of the total volume of oxygen and ozone in the mixed gas.

### 6. Effects of First Embodiment

The β-gallium oxide film production apparatus 1000 according to the first embodiment includes the first plasma generation unit and the second plasma generation unit. The first plasma generation unit generates the mixed gas containing oxygen and ozone by generating plasma from the oxygen gas. The second plasma generation unit dissociates ozone by generating plasma from the mixed gas containing oxygen and ozone.

Accordingly, near the surface of the β-gallium oxide substrate 110, Ga reacts with the singlet oxygen atom or the triplet oxygen atom O (³P) resulting from transition of the singlet oxygen atom O (¹D) to grow the β-gallium oxide film 120. By using the production apparatus 1000 according to the first embodiment, many singlet oxygen atoms or triplet oxygen atoms O (³P) resulting from transition of the singlet oxygen atoms O (¹D) reach the surface of the β-gallium oxide substrate 110, and the β-gallium oxide film 120 having excellent crystallinity and good flatness is grown. In addition, a film formation rate for the β-gallium oxide film 120 in the case of using the production apparatus 1000 according to the first embodiment is faster than a film formation rate for a β-gallium oxide film in the case of using a production apparatus in the related art.

### 7. Modifications

### 7-1. Substrate

Instead of the β-gallium oxide substrate 110, other substrates such as an α-gallium oxide substrate may be used. The crystal orientation may also be selected depending on an application. The other substrate is a substrate for epitaxially growing a gallium oxide. Therefore, the substrate has a single crystal or a crystal close to a single crystal of the gallium oxide on the surface.

### 7-2. Ozonizer

The ozonizer may generate plasma by a method other than the dielectric barrier discharge. Alternatively, ozone may be generated by a method other than plasma. For example, ozone may be generated by irradiating oxygen with ultraviolet light.

### 7-3. Excited State of Ozone

In the first embodiment, the ozonizer 1700 converts an oxygen gas into a mixed gas containing oxygen and ozone. The mixed gas may include an excited state of ozone.

### 7-4. Dissociation of Oxygen Molecule

The plasma generation unit 1450 may dissociate an oxygen molecule into an oxygen radical.

### 7-5. Plasma Generation Unit

The oxygen element supply device 1400 may generate plasma in the plasma generation chamber PS1 by a method other than the ICP antenna.

### 7-6. Inert Gas

As the inert gas for generating plasma, rare gases other than Ar, such as He or Ne, may be used. Depending on growth conditions, it may not be necessary to supply an inert gas. That is, in this case, the production apparatus does not include the inert gas supply unit 1600. In this case, a mixed gas containing oxygen and ozone is supplied into the oxygen element supply device 1400 through the mixed gas supply pipe 1870. In this case, the inert gas supply pipe 1850 and the like are not necessary.

### 7-7. Impurity Element Supply Unit

The production apparatus 1000 may include an impurity element supply unit that supplies an impurity. The impurity element supply unit supplies an impurity element to grow an n-type gallium oxide or a β-type gallium oxide.

### 7-8. Breakdown Voltage

A breakdown voltage of the gallium oxide film can be measured using a curve tracer. The breakdown voltage of the gallium oxide film has a lower limit value of preferably 16 V/μm or more, more preferably 20 V/μm or more, still more preferably 30 V/μm or more, even more preferably 50 V/μm or more, particularly preferably 80 V/μm or more, more particularly preferably 100 V/μm or more, and most preferably 105 V/μm or more. In addition, the breakdown voltage of the gallium oxide film is not particularly limited in upper limit. The breakdown voltage of the gallium oxide film may be, for example, 400 V/μm or less, 250 V/μm or less, or 200 V/μm or less.

The breakdown voltage is, for example, 100 V/μm or more and 400 V/μm or less.

### 7-9. Thickness

The thickness of the gallium oxide film can be measured using a scanning electron microscope or the like. The thickness of the gallium oxide film has a lower limit value of preferably 0.5 μm or more, more preferably 0.8 μm or more, and still more preferably 1 μm or more. In addition, the thickness of the gallium oxide film is not particularly limited in upper limit, and in view of the film formation rate and a film quality, it is preferably 50 μm or less. The thickness of the gallium oxide film is, for example, 0.5 μm or more and 50 μm or less. The thickness of the gallium oxide film may be, for example, 0.8 μm or more and 30 μm or less, or 1 μm or more and 20 μm or less.

### 7-10. Surface Roughness

A surface roughness (Ra) of the gallium oxide film can be measured using an atomic force microscope or the like. In the case of using an atomic force microscope, the surface roughness (Ra) of the gallium oxide film is measured in a range of 10×10⁻⁸ cm², and the surface roughness (Ra) is calculated.

The surface roughness (Ra) of the gallium oxide film has an upper limit value of preferably 2.0 nm or less, more preferably 1.5 nm or less, and still more preferably 1.0 nm or less. In addition, the surface roughness (Ra) of the gallium oxide film is not particularly limited in lower limit since when it is too large, problems may occur during apparatus fabrication. It is preferably 0.1 nm or more. The surface roughness (Ra) of the gallium oxide film is, for example, 0.1 nm or more and 2.0 nm or less. The surface roughness (Ra) of the gallium oxide film may be, for example, 0.1 nm or more and 1.5 nm or less.

### 7-11. Crystallinity (Full Width at Half Maximum)

A full width at half maximum of the gallium oxide film in X-ray diffraction is calculated based on a diffraction peak that belongs to a (002) plane among diffraction peaks that belong to a β-gallium oxide, for example. In the present description, the full width at half maximum also refers to FWHM. The full width at half maximum of the gallium oxide film can be measured using a crystal X-ray diffraction device (CuKα rays).

The FWHM of the gallium oxide film has an upper limit value of preferably 80 arcsec or less, more preferably 70 arcsec or less, and still more preferably 60 arcsec or less. In addition, the FWHM of the gallium oxide film is not particularly limited in lower limit, and is preferably 15 arcsec or more. The full width at half maximum of the gallium oxide film is, for example, 15 arcsec or more and 80 arcsec or less in the X-ray diffraction. The full width at half maximum of the gallium oxide film may be, for example, 15 arcsec or more and 70 arcsec or less in the X-ray diffraction.

### 7-12. Combination

In some cases, the modifications of the first embodiment may be combined as appropriate.

Although the gallium oxide film and the production apparatus and the production method for the same according to the present embodiment have been described in detail above, other embodiments according to the present embodiment are as follows.

[1] A gallium oxide film production apparatus including:
a reaction chamber;
a substrate disposition portion located in the reaction chamber and configured to dispose a substrate for growing a gallium oxide;
a gallium element supply device configured to supply a gallium element to the substrate disposition portion;
an oxygen element supply device configured to supply oxygen constituent particles to the substrate disposition portion; and
a mixed gas supply device configured to supply a mixed gas containing oxygen and ozone to the oxygen element supply device,
in which the oxygen element supply device includes a plasma generation unit configured to generate plasma from the mixed gas.

[2] The gallium oxide film production apparatus according to the above [1], in which the mixed gas supply device has a function of setting a concentration of the ozone to 5 vol % or more of a total volume of the oxygen and the ozone in the mixed gas.

[3] A gallium oxide film production method including:
generating plasma from a mixed gas containing oxygen and ozone to dissociate the ozone into oxygen constituent particles, and supplying the oxygen constituent particles to a reaction chamber under a reduced pressure;
supplying a gallium element to the reaction chamber; and
epitaxially growing a β-gallium oxide on a β-gallium oxide substrate in the reaction chamber.

[4] The gallium oxide film production method according to the above [3], including setting a concentration of the ozone to 5 vol % or more of a total volume of the oxygen and the ozone in the mixed gas.

[5] The gallium oxide film production method according to the above [3] or [4], including setting a temperature of the β-gallium oxide substrate to 0° C. or higher and 700° C. or lower.

[6] A gallium oxide film having a thickness of 0.5 μm or more and a breakdown voltage of 80 V/μm or more.

[7] The gallium oxide film according to the above [6], in which the breakdown voltage is 100 V/μm or more and 400 V/μm or less.

[8] The gallium oxide film according to the above [6] or [7], in which the thickness is 0.5 μm or more and 50 μm or less.

[9] The gallium oxide film according to any one of the above [6] to [8], having a full width at half maximum of 15 arcsec or more and 80 arcsec or less in X-ray diffraction.

[10] The gallium oxide film according to any one of the above [6] to [9], having a surface roughness (Ra) of 0.1 nm or more and 2.0 nm or less.

[11] The gallium oxide film according to any one of the above [6] to [10],
in which the gallium oxide film is formed on a gallium oxide substrate, and
the gallium oxide film is a gallium oxide single crystal.

[12] The gallium oxide film according to the above [11], in which the gallium oxide single crystal is a crystal that belongs to a β-gallium oxide.

[13] The gallium oxide film according to the above [12], in which the gallium oxide film is oriented in a (001) plane.

[14] The gallium oxide film according to the above [12], in which the gallium oxide substrate is oriented in a (001) plane.

[15] The gallium oxide film according to the above [12], in which the gallium oxide film is oriented in a (40-1) plane.

[16] The gallium oxide film according to the above [12], in which the gallium oxide film is oriented in a (010) plane.

### EXAMPLES

### (Experiments)

### A. Experiment 1

### 1. Experiment Method

### 1-1. Production Apparatus

The production apparatus 1000 was used.

### 1-2. Experiment Conditions

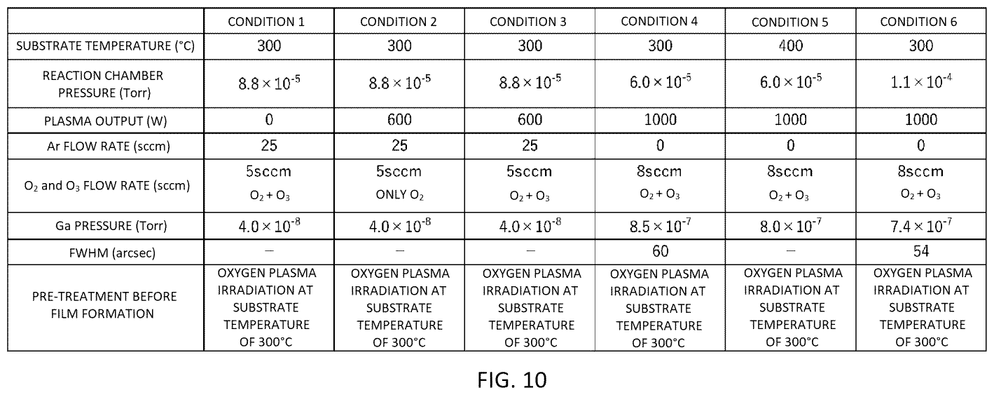

FIG. 10 is a table showing experiment conditions for producing a gallium oxide film. Main differences between a condition 1 to a condition 6 can be summarized as follows. FIG. 10 also shows FWHM values of β-gallium oxides obtained under the condition 4 to the condition 6.
Condition 1: ozone supply, no second plasma output
Condition 2: no ozone supply, second plasma output
Condition 3: ozone supply, second plasma output
Condition 4: ozone supply, second plasma output
Condition 5: ozone supply, second plasma output
Condition 6: ozone supply, second plasma output

Note that, under the condition 4, an Ar gas is not mixed into the mixed gas for generating plasma. In addition, a plasma output value, a flow rate of the mixed gas for generating plasma, and a Ga pressure under the condition 4 are greater than a plasma output value, a flow rate of the mixed gas for generating plasma, and a Ga pressure under the condition 3.

Note that, under the condition 5, an Ar gas is not mixed into the mixed gas for generating plasma. In addition, a plasma output value, a flow rate of the mixed gas for generating plasma, and a Ga pressure under the condition 5 are greater than the plasma output value, the flow rate of the mixed gas for generating plasma, and the Ga pressure under the condition 3. In addition, the flow rate of the mixed gas for generating plasma is greater than that under the condition 4.

Note that, under the condition 6, an Ar gas is not mixed into the mixed gas for generating plasma. In addition, a plasma output value, a flow rate of the mixed gas for generating plasma, and a Ga pressure under the condition 6 are greater than the plasma output value, the flow rate of the mixed gas for generating plasma, and the Ga pressure under the condition 3.

In all of the condition 1 to the condition 6, a film formation time was 60 minutes. A material of the substrate was a bulk (001) β-gallium oxide substrate. In addition, in the present experiment, the internal pressure of the furnace during growth was set to 8.8×10⁻⁵ Torr, 6.0×10⁻⁵ Torr, or 1.1×10⁻⁴ Torr. When the internal pressure of the furnace is too high, the radicals collide with each other, resulting in an insufficient radical density, and when the internal pressure of the furnace is too low, the oxygen radical supplied from a plasma source is insufficient, making it impossible to grow a gallium oxide. This pressure varies depending on a structure and a size of the furnace and a distance between the substrate and a radical source, and therefore needs to be optimized.

### 2. Experiment Result 1

### 2-1. Condition 1

FIG. 11 is a scanning electron microscope photograph showing a surface of a deposit on a substrate in the case where a mixed gas containing oxygen, ozone, and an Ar gas is not irradiated with second plasma.

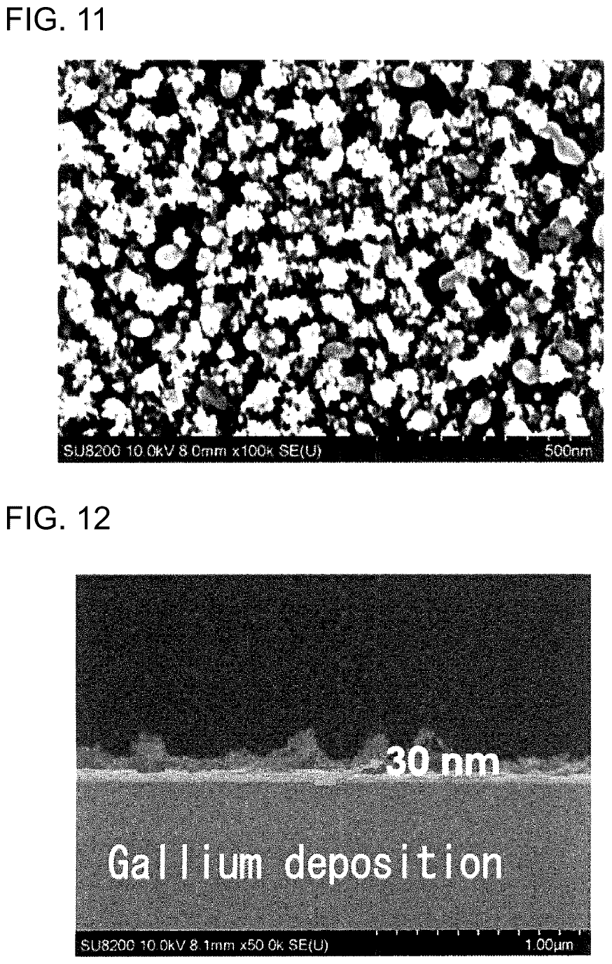

FIG. 12 is a scanning electron microscope photograph showing a cross section of the deposit on the substrate in the case where the mixed gas containing oxygen, ozone, and an Ar gas is not irradiated with the second plasma.

As shown in FIG. 11 and FIG. 12, the surface of the deposit was rough. In addition, as shown in FIG. 12, gallium accumulated on the substrate, making it impossible to grow a β-gallium oxide.

### 2-2. Condition 2

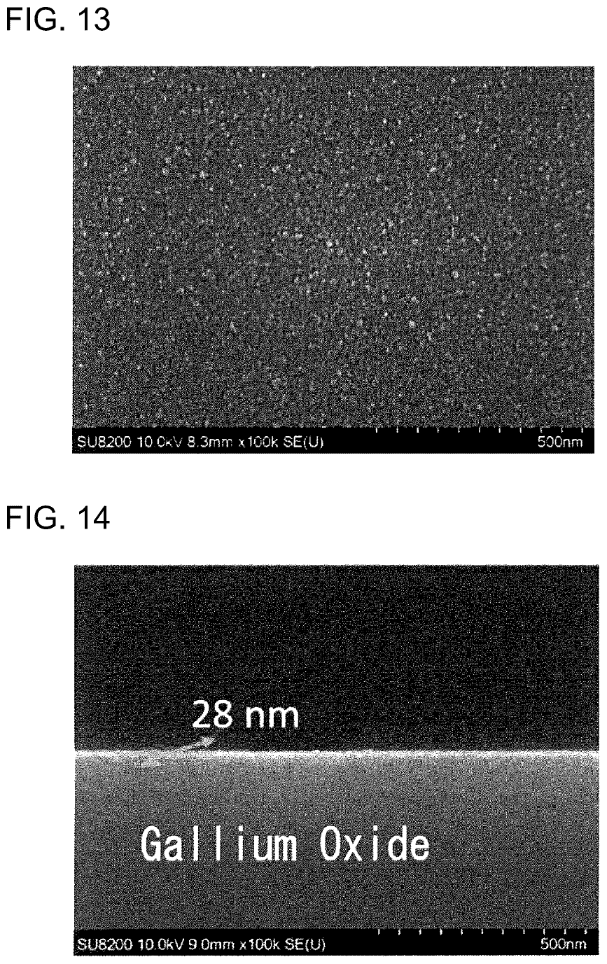

FIG. 13 is a scanning electron microscope photograph showing a surface of a deposit on the substrate in the case where a mixed gas containing oxygen and an Ar gas is irradiated with the second plasma.

FIG. 14 is a scanning electron microscope photograph showing a cross section of the deposition on the substrate in the case where the mixed gas containing oxygen and an Ar gas is irradiated with the second plasma.

As shown in FIG. 13, the surface of the deposit was only slightly rough. As shown in FIG. 14, a β-gallium oxide was deposited. The β-gallium oxide had a film thickness of about 28 nm. The film formation rate was 0.47 nm/min.

### 2-3. Condition 3

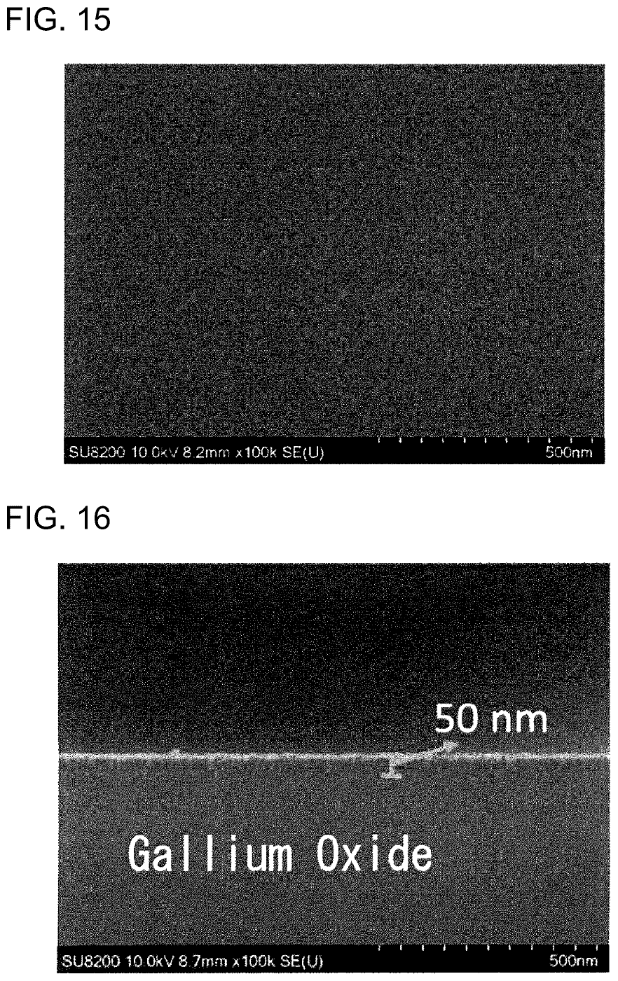

FIG. 15 is a scanning electron microscope photograph showing a surface of a deposit on the substrate in the case where the mixed gas containing oxygen, ozone, and an Ar gas is irradiated with the second plasma.

FIG. 16 is a scanning electron microscope photograph showing a cross section of the deposit on the substrate in the case where the mixed gas containing oxygen, ozone, and an Ar gas is irradiated with the second plasma.

As shown in FIG. 15, a surface of a growth was almost completely not rough. As shown in FIG. 16, a β-gallium oxide was grown. The β-gallium oxide had a film thickness of about 50 nm. The film formation rate was 0.83 nm/min.

### 2-4. Condition 4

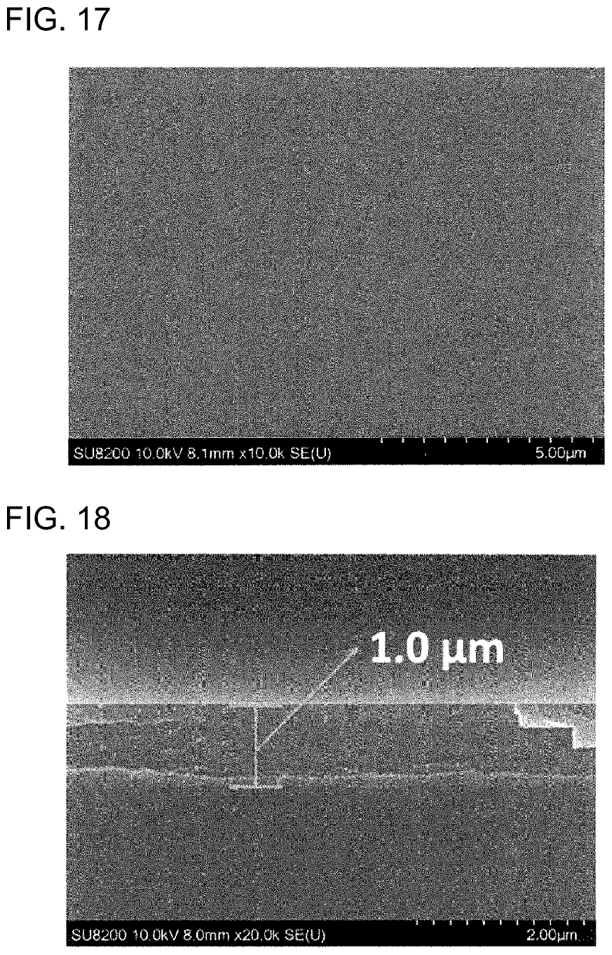

FIG. 17 is a scanning electron microscope photograph showing a surface of a deposit on the substrate in the case where a mixed gas containing oxygen and ozone is irradiated with the second plasma.

FIG. 18 is a scanning electron microscope photograph showing a cross section of the deposit on the substrate in the case where the mixed gas containing oxygen and ozone is irradiated with the second plasma.

As shown in FIG. 17, a surface of a growth was very clean. The β-gallium oxide had high flatness. As shown in FIG. 18, the grown β-gallium oxide had a film thickness of 1 μm. The film formation rate was 16.7 nm/min (1.0 μm/hr).

The surface roughness (Ra) of the film immediately after film formation was measured by using an atomic force microscope and was 0.9 nm.

In this way, under the condition 3 (ozone introduced, plasma power: 600 W) and the condition 4 (ozone introduced, plasma power: 1000 W), in which a mixed gas containing oxygen and ozone is converted into plasma, the film formation rate is much faster than in that under the condition 1 (ozone introduced, no plasma) and the condition 2 (no ozone introduced, plasma power: 600 W). In addition, under the condition 4, a gallium oxide film having a large thickness could be produced. Further, the surface of the gallium oxide film was very smooth. As shown in the present experiment, the effect of ozone-introduced plasma irradiation is clear.

### 3. Experiment Result 2

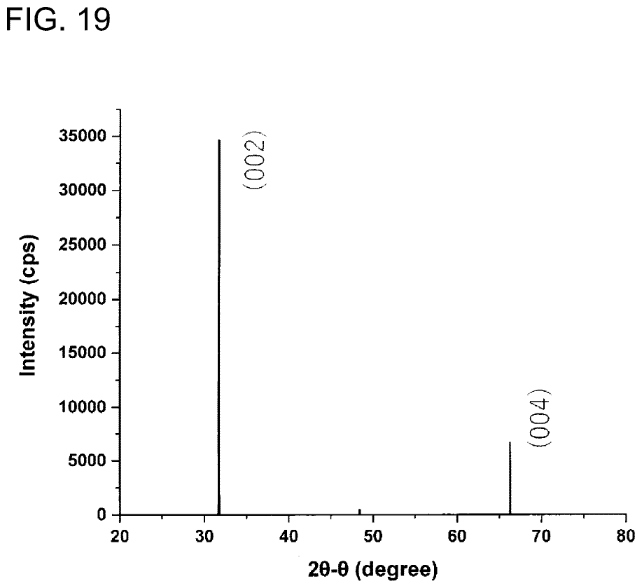

FIG. 19 is a pattern showing an X-ray diffraction result of a β-gallium oxide substrate. The horizontal axis in FIG. 19 is 2θ-θ (°). The vertical axis in FIG. 19 is intensity.

As shown in FIG. 19, a (002) peak and a (004) peak were observed. The (002) peak had a FWHM of 30 arcsec.

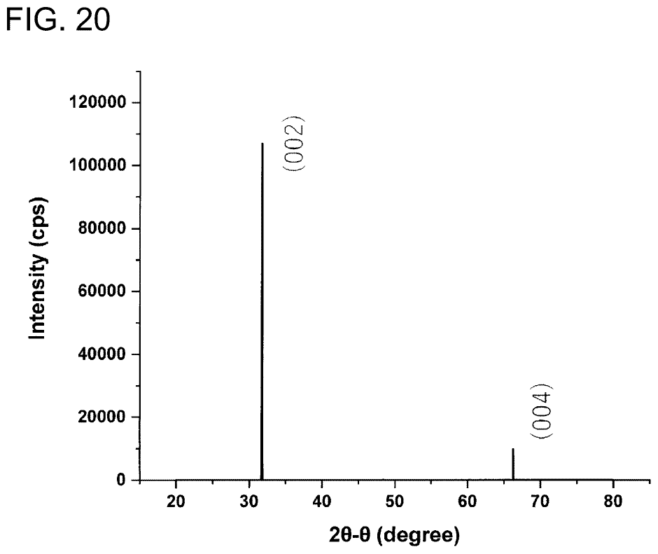

FIG. 20 is a pattern showing an X-ray diffraction result of a β-gallium oxide film formed on the substrate under the condition 4. The horizontal axis in FIG. 20 is 2θ-θ (°). The vertical axis in FIG. 20 is intensity.

As shown in FIG. 20, a (002) peak and a (004) peak were observed. The (002) peak had a FWHM of 60 arcsec. In this way, the FWHM was very narrow, and the crystallinity of the β-gallium oxide was excellent.

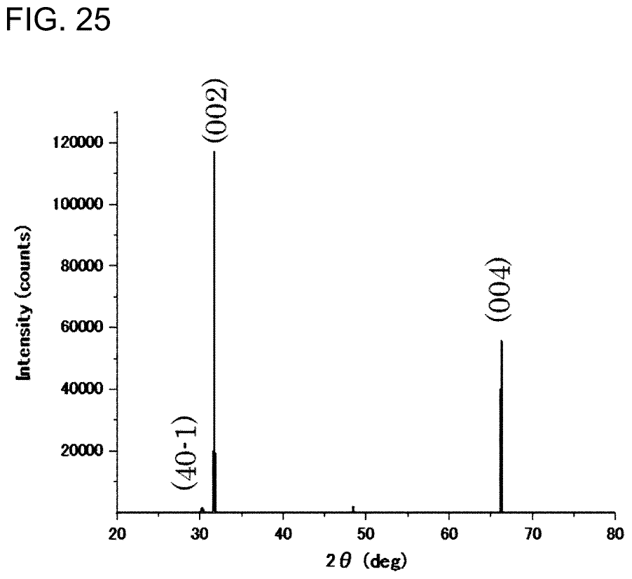

FIG. 25 is a pattern showing an X-ray diffraction result of a β-gallium oxide film formed on the substrate under the condition 5. The horizontal axis in FIG. 25 is 2θ-θ (°). The vertical axis in FIG. 25 is intensity.

As shown in FIG. 25, a (40-1) peak was observed.

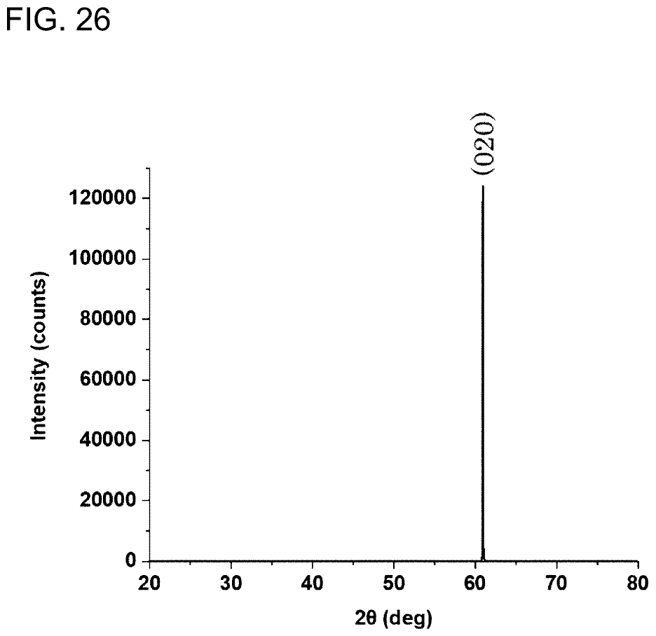

FIG. 26 is a pattern showing an X-ray diffraction result of a β-gallium oxide film formed on the substrate under the condition 6. The horizontal axis in FIG. 26 is 2θ-θ (°). The vertical axis in FIG. 26 is intensity.

As shown in FIG. 26, a (010) peak was observed. The (010) peak had a FWHM of 54 arcsec. In this way, the FWHM was very narrow, and the crystallinity of the β-gallium oxide was excellent.

In this way, under the condition 4 in which the mixed gas containing oxygen and ozone was converted into plasma, the film formation rate was very high. In addition, the formed gallium oxide film had a large thickness. A gallium oxide film having a very smooth surface and excellent crystallinity was obtained.

### B. Experiment 2

An experiment was carried out to compare the amount of oxygen atoms generated in the case where the gas supplied to the oxygen element supply device 1400 was an oxygen gas alone and in the case where the gas further contained ozone.

### 1. Experiment Method

Using the production apparatus 1000, the density of the oxygen atom was measured. The internal pressure in the reaction chamber 1100 was 5 Pa. The plasma output was 900 W. The flow rate of the Ar gas was 12 sccm. The flow rate of the oxygen gas or the mixed gas containing oxygen and ozone was 2 sccm.

The concentration of ozone in the mixed gas containing oxygen and ozone was calculated to be 28 vol %. The concentration of ozone was calculated based on a relationship between the flow rate of the oxygen gas and the concentration of ozone in the ozonizer.

### 2. Experiment Result

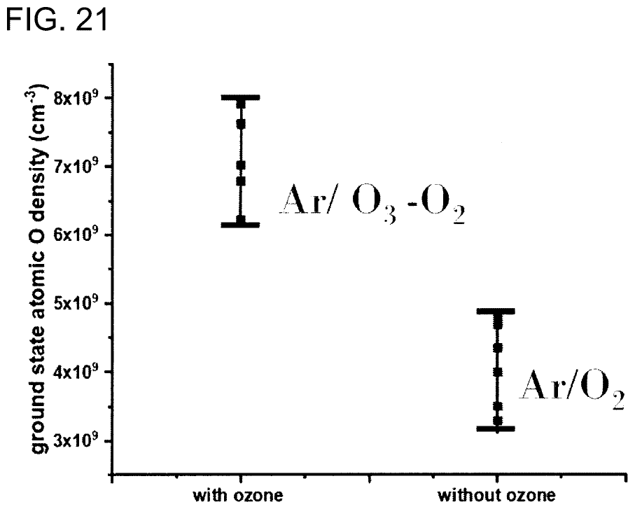

FIG. 21 is a graph showing a density of the triplet oxygen atom O (³P). The horizontal axis in FIG. 21 indicates the presence or absence of ozone. The vertical axis in FIG. 21 represents the density (cm⁻³) of the triplet oxygen atom O (³P).

As shown in FIG. 21, in the case where only oxygen was supplied to the oxygen element supply device 1400 and oxygen was converted into plasma, the average density of the triplet oxygen atom O (³P) was approximately 4×10⁹ cm⁻³. In the case where a mixed gas containing oxygen and ozone was supplied to the oxygen element supply device 1400 and the mixed gas was converted into plasma, the average density of the triplet oxygen atom O (³P) was approximately 7×10⁹ cm⁻³.

Therefore, in the case where the mixed gas containing oxygen gas and ozone is used instead of the oxygen gas, the density of the triplet oxygen atom O (³P) increases by about 75%.

Note that, the singlet oxygen atom O (¹D) is in an excited state about 1.97 eV higher than the triplet oxygen atom O (³P), and therefore easily transitions to the triplet oxygen atom O (³P). That is, the measured value for the triplet oxygen atom O (³P) includes the oxygen atom that is once the singlet oxygen atom O (¹D).

### C. Experiment 3

### 1. Experiment Method

Using the condition 4 in the experiment 1, a β-gallium oxide film was formed on a substrate.

### 2. Experiment Result

### 2-1. Breakdown Voltage

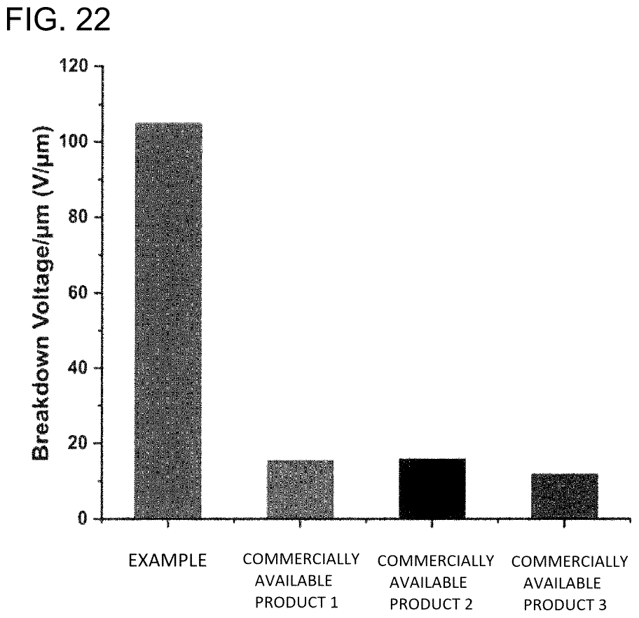

FIG. 22 shows the breakdown voltage (V/μm) of the β-gallium oxide film. As shown in FIG. 22, the β-gallium oxide film had a breakdown voltage of 105 V/μm. A β-gallium oxide film in the related art has a breakdown voltage of about 15 V/μm.

In this way, in the case where of using the condition 4 in which the mixed gas containing oxygen and ozone was converted into plasma, a gallium oxide film having excellent properties, having a thickness being as thick as 1 μm and a breakdown voltage of 100 V/μm or more, could be obtained.

In the related art, in order to obtain a film having a breakdown voltage of 100 V/μm or more, it is necessary to carry out MBE film formation, which has a very slow growth rate, and it is not realistic to obtain a thick film, for example, 0.5 μm or more. Particularly, in the related art, the β-gallium oxide has a growth rate of a film oriented in the (001) plane slower than a growth rate of a film oriented in another plane (for example the (010) plane). Therefore, it has been practically difficult to form a thick film (for example, 0.5 μm or more). In addition, in the related art, in the case of selecting a method with a fast growth rate, only a film having a breakdown voltage of less than 100 V/μm (for example, less than 80 V/μm) can be obtained.

Therefore, the crystallinity of the β-gallium oxide film in the present experiment is more excellent than the crystallinity of the β-gallium oxide film in the related art.

### 2-2. Current-Voltage Properties

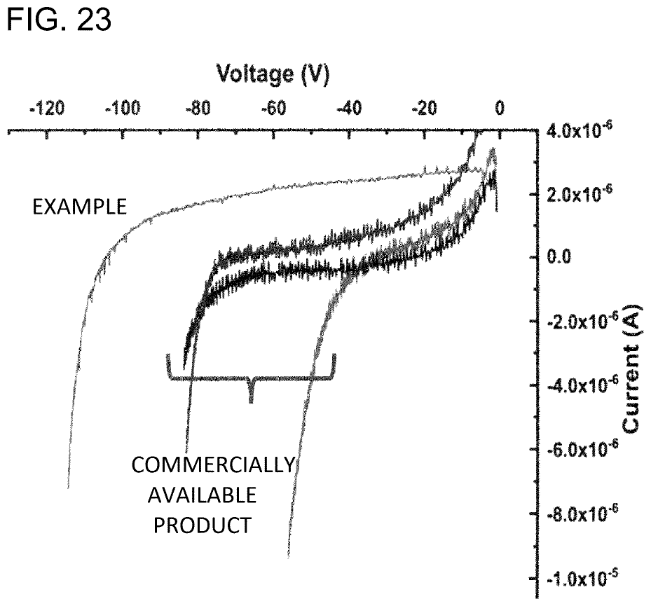

FIG. 23 is a graph showing current-voltage properties of a β-gallium oxide film.

### D. Experiment 4

### 1. Experiment Method

The β-gallium oxide was grown by changing a partial pressure of the gallium element supplied to the reaction chamber and the growth temperature.

### 2. Experiment Result

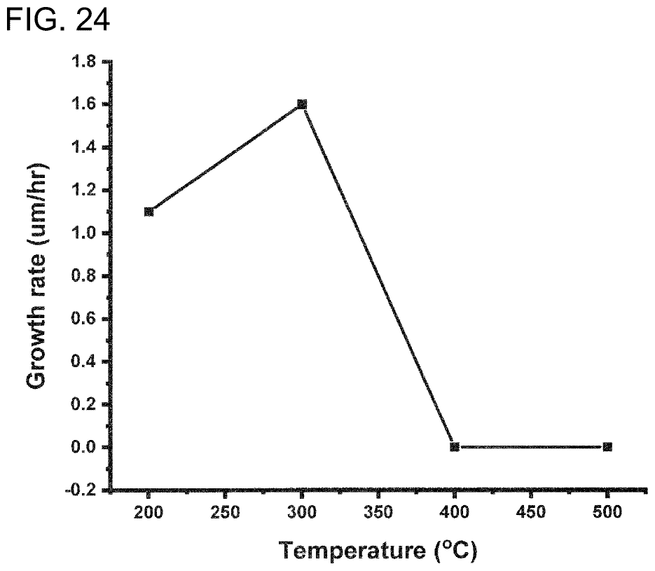

FIG. 24 is a graph showing a relationship between the growth temperature and the growth rate of the β-gallium oxide film. The horizontal axis in FIG. 24 is the temperature of the substrate during growth. The vertical axis in FIG. 24 is the growth rate of the β-gallium oxide.

As shown in FIG. 24, in the case where the temperature of the substrate was 200° C. or 300° C., a β-gallium oxide film could be grown. In the case where the temperature of the substrate was 200° C., the growth rate of the β-gallium oxide film was approximately 1.1 μm/hr. In the case where the temperature of the substrate was 300° C., the growth rate of the β-gallium oxide film was approximately 1.6 μm/hr. In the case where the temperature of the substrate was 400° C. and 500° C., the β-gallium oxide film hardly grew. Note that, increasing the density of oxidizing radicals allows the growth of the β-gallium oxide film at a higher temperature.

### APPENDIXES

A gallium oxide film production apparatus according to a first aspect includes: a reaction chamber; a substrate disposition portion in the reaction chamber and configured to dispose a substrate for growing a gallium oxide; a gallium element supply device configured to supply a gallium element to the substrate disposition portion; an oxygen element supply device configured to supply oxygen constituent particles to the substrate disposition portion; and a mixed gas supply device configured to supply a mixed gas containing oxygen and ozone to the oxygen element supply device. The oxygen element supply device includes a plasma generation unit configured to generate plasma from the mixed gas.

A gallium oxide film production apparatus according to a second aspect is based on the first aspect, in which the mixed gas supply device has a function of setting a concentration of the ozone to 5 vol % or more of a total volume of the oxygen and the ozone in the mixed gas.

A gallium oxide film production method according to a third aspect includes: generating plasma from a mixed gas containing oxygen and ozone to dissociate the ozone into oxygen constituent particles, and supplying the oxygen constituent particles to a reaction chamber under a reduced pressure; supplying a gallium element to the reaction chamber; and epitaxially growing a β-gallium oxide on a β-gallium oxide substrate in the reaction chamber.

A gallium oxide film production method according to a fourth aspect is based on the third aspect, and further includes setting a concentration of the ozone to 5 vol % or more of a total volume of the oxygen and the ozone in the mixed gas.

A gallium oxide film production method according to a fifth aspect is based on the third aspect or the fourth aspect, and further includes setting a temperature of the β-gallium oxide substrate to 0° C. or higher and 700° C. or lower.

A gallium oxide film according to a sixth aspect has a thickness of 0.5 μm or more and a breakdown voltage of 80 V/μm or more.

A gallium oxide film according to a seventh aspect is based on the sixth aspect, in which the breakdown voltage is 100 V/μm or more and 400 V/μm or less.

A gallium oxide film according to an eighth aspect is based on the sixth aspect or the seventh aspect, in which the thickness is 0.5 μm or more and 50 μm or less.

A gallium oxide film according to an ninth aspect is based on any one of the sixth aspect to the eighth aspect, in which the gallium oxide film has a full width at half maximum of 15 arcsec or more and 80 arcsec or less in X-ray diffraction.

A gallium oxide film according to a tenth aspect is based on any one of the sixth aspect to the ninth aspect, in which the gallium oxide film has a surface roughness (Ra) of 0.1 nm or more and 2.0 nm or less.

A gallium oxide film according to an eleventh aspect is based on any one of the sixth aspect to the tenth aspect, in which the gallium oxide film is formed on a gallium oxide substrate, and the gallium oxide film is a gallium oxide single crystal.

A gallium oxide film according to a twelfth aspect is based on the eleventh aspect, in which the gallium oxide single crystal is a crystal that belongs to a β-gallium oxide.

A gallium oxide film according to a thirteenth aspect is based on the twelfth aspect, in which the gallium oxide film is oriented in a (001) plane.

A gallium oxide film according to a fourteenth aspect is based on the twelfth aspect or the thirteenth aspect, in which the gallium oxide substrate is oriented in a (001) plane.

A gallium oxide film according to a fifteenth aspect is based on the twelfth aspect, in which the gallium oxide film is oriented in a (40-1) plane.

A gallium oxide film according to a sixteenth aspect is based on the twelfth aspect, in which the gallium oxide film is oriented in a (010) plane.

Although the present invention has been described in detail with reference to specific embodiments, it is apparent to those skilled in the art that various changes and modifications can be made without departing from the spirit and scope of the present invention. The present application is based on a Japanese Patent Application (No. 2022-050538) filed on Mar. 25, 2022, and a Japanese Patent Application (No. 2023-024459) filed on Feb. 20, 2023, and the contents of which are incorporated herein by reference.

### REFERENCE SIGNS LIST

1000: production apparatus
1100: reaction chamber
1200: substrate disposition portion
1300: gallium element supply device
1400: oxygen element supply device
1500: oxygen gas supply unit
1600: inert gas supply unit
1700: ozonizer
1800: mixed gas supply device

1. A gallium oxide film production apparatus comprising:
a reaction chamber;
a substrate disposition portion located in the reaction chamber and configured to dispose a substrate for growing a gallium oxide;
a gallium element supply device configured to supply a gallium element to the substrate disposition portion;
an oxygen element supply device configured to supply oxygen constituent particles to the substrate disposition portion; and
a mixed gas supply device configured to supply a mixed gas comprising oxygen and ozone to the oxygen element supply device, wherein
the oxygen element supply device comprises a plasma generation unit configured to generate plasma from the mixed gas.

2. The gallium oxide film production apparatus according to claim 1, wherein the mixed gas supply device has a function of setting a concentration of the ozone to 5 vol % or more of a total volume of the oxygen and the ozone in the mixed gas.

3. A gallium oxide film production method comprising:
generating plasma from a mixed gas comprising oxygen and ozone to dissociate the ozone into oxygen constituent particles, and supplying the oxygen constituent particles to a reaction chamber under a reduced pressure;
supplying a gallium element to the reaction chamber; and
epitaxially growing a β-gallium oxide on a β-gallium oxide substrate in the reaction chamber.

4. The gallium oxide film production method according to claim 3, comprising:
setting a concentration of the ozone to 5 vol % or more of a total volume of the oxygen and the ozone in the mixed gas.

5. The gallium oxide film production method according to claim 3, comprising:
setting a temperature of the β-gallium oxide substrate to 0° C. or higher and 700° C. or lower.

6. A gallium oxide film having a thickness of 0.5 μm or more and a breakdown voltage of 80 V/μm or more.

7. The gallium oxide film according to claim 6, wherein the breakdown voltage is 100 V/μm or more and 400 V/μm or less.

8. The gallium oxide film according to claim 6, wherein the thickness is 0.5 μm or more and 50 μm or less.

9. The gallium oxide film according to claim 6, having a full width at half maximum of 15 arcsec or more and 80 arcsec or less in X-ray diffraction.

10. The gallium oxide film according to claim 6, having a surface roughness (Ra) of 0.1 nm or more and 2.0 nm or less.

11. The gallium oxide film according to claim 6,
wherein the gallium oxide film is formed on a gallium oxide substrate, and
the gallium oxide film is a gallium oxide single crystal.

12. The gallium oxide film according to claim 11, wherein the gallium oxide single crystal is a crystal that belongs to a β-gallium oxide.

13. The gallium oxide film according to claim 12, wherein the gallium oxide film is oriented in a (001) plane.

14. The gallium oxide film according to claim 12, wherein the gallium oxide substrate is oriented in a (001) plane.

15. The gallium oxide film according to claim 12, wherein the gallium oxide film is oriented in a (40-1) plane.

16. The gallium oxide film according to claim 12, wherein the gallium oxide film is oriented in a (010) plane.
